(19) United States
(12) Patent Application Publication
(10) Pub. No.: US 2008/0233718 A1
(43) Pub. Date: Sep. 25, 2008

(54) Method of Semiconductor Thin Film Crystallization and Semiconductor Device Fabrication

(76) Inventors: Jia-Xing Lin, Hsinchu County (TW); Fang-Tsun Chu, Taichung County (TW); Hung-Tse Chen, Hsinchu County (TW)

Correspondence Address: Akin Gump LLP - Silicon Valley, 3000 El Camino Real, Two Palo Alto Square, Suite 400, Palo Alto, CA, 94306, US

(21) Appl. No.: 11/689,498

(22) Filed: Mar. 21, 2007

(51) Int. Cl. H01L 21/20

(52) U.S. Cl. 438/486

(57) ABSTRACT

A method of fabricating a semiconductor device includes providing a substrate, forming an amorphous silicon layer over the substrate, forming a patterned heat retaining layer over the amorphous silicon layer, doping the amorphous silicon layer to form a pair of doped regions in the amorphous silicon layer by using the patterned heat retaining layer as a mask, and irradiating the amorphous silicon layer to activate the pair of doped regions, forming a pair of activated regions, and form a crystallized region between the pair of activated regions.

### BACKGROUND OF THE INVENTION

The present invention relates generally to semiconductor manufacturing, and more particularly, to a method of semiconductor thin film crystallization and semiconductor device fabrication.

Polycrystalline silicon thin film as a high quality active layer in semiconductor devices has recently attracted considerable attention due to its superior charge carrier transport property and high compatibility with current semiconductor device fabrication. With low temperature process, it is possible to fabricate reliable polycrystalline silicon thin film transistors (“TFTs”) on transparent glass or plastic substrates for making polycrystalline silicon more competitive in the application of large area flat panel displays such as active matrix liquid crystal displays (“AMLCDs”) or active matrix organic light emitting diode displays (“OLEDs”).

The importance of polycrystalline silicon TFTs comprises a superior display performance such as high pixel aperture ratio, low driving power consumption, high device reliability, and among others, an enabling feature of integrating various peripheral driver components directly onto the glass substrate. Peripheral circuit integration is not only beneficial in reducing the running cost, but also in enriching the functionality for mobile purpose applications. However, the device performance of polycrystalline silicon TFTs, such as carrier mobility, is significantly affected by the crystal grain size. The carrier flow in an active channel has to overcome the energy barrier of the grain boundary between each crystal grain, and thus the carrier mobility decreases. Therefore, in order to improve the device performance, it is very important to reduce the number of polycrystalline silicon grain boundaries within the active channel. To fulfill the requirement, grain size enlargement and grain boundary location control within the active channel are the two possible manipulations.

Conventional methods for fabricating polycrystalline silicon thin film comprise solid phase crystallization (“SPC”) and direct chemical vapor phase deposition (“CVD”). These techniques are not applicable to high performance flat panel displays because the crystalline quality is limited by the low process temperature (typically lower than 650° C.) and the grain size of polycrystalline silicon thus fabricated is as small as 100 nm (nanometer). Hence, the electrical characteristics of polycrystalline silicon thin films are limited.

The excimer laser annealing (“ELA”) method is currently the most commonly used method in polycrystalline silicon TFT fabrication. The grain size of polycrystalline silicon thin film can reach 300-600 nm, and the carrier mobility of polycrystalline silicon TFTs can reach 200 cm²/V-s. However, this value is yet not sufficient for future demand of high performance flat panel displays. Furthermore, unstable laser energy output of ELA narrows down the process window generally to several tens of mJ/cm². As a result, frequently repeated laser irradiation is necessary to re-melt imperfect fine grains caused by the irregular laser energy fluctuation. The repeated laser irradiation may render ELA less competitive due to its high cost in process optimization and system maintenance.

Although a few methods for enlarging grain size of polycrystalline silicon have been set forth recently, these methods such as sequential lateral solidification (“SLS”) and phase modulated ELA (“PMELA”) all still require additional modification and further process parameter control for the current ELA systems. It is therefore desirable to have a method of semiconductor thin film crystallization that can achieve greater, uniform grain size and a precise control of grain boundary in a cost efficient manner without compromising desired electrical properties.

### BRIEF SUMMARY OF THE INVENTION

Examples of the invention may provide a method of fabricating a semiconductor device that comprises providing a substrate, forming an amorphous silicon layer over the substrate, forming a patterned heat retaining layer over the amorphous silicon layer, doping the amorphous silicon layer to form a pair of doped regions in the amorphous silicon layer by using the patterned heat retaining layer as a mask, and irradiating the amorphous silicon layer to activate the pair of doped regions, forming a pair of activated regions, and form a crystallized region between the pair of activated regions.

Examples of the invention may also provide a method of fabricating a semiconductor device that comprises providing a substrate, forming an amorphous silicon layer over the substrate, forming a heat retaining layer over the amorphous silicon layer, patterning the heat retaining layer to form a patterned heat retaining layer without exposing the amorphous silicon layer, doping the amorphous silicon layer through the patterned heat retaining layer to form a pair of doped regions in the amorphous silicon layer, and activating the pair of doped regions to form a pair of activated regions, and forming a crystallized region between the pair of activated regions by irradiating the amorphous silicon layer through the patterned heat retaining layer.

Some examples of the invention may also provide a method of fabricating a semiconductor device that comprises providing a substrate, forming an amorphous silicon layer over the substrate, forming an insulating layer over the amorphous silicon layer, forming a patterned heat retaining layer over the insulating layer, doping the amorphous silicon layer to form a pair of doped regions in the amorphous silicon layer, and activating the pair of doped regions to form a pair of activated regions, and forming a crystallized region between the pair of activated regions by irradiating the amorphous silicon layer through the patterned heat retaining layer.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings examples consistent with the invention. It should be understood, however, that the invention is not limited to the precise arrangements and instrumentalities shown.

In the drawings:

FIGS. 1A to 1H are schematic diagrams illustrating a method of fabricating a semiconductor device consistent with an example of the present invention;

FIGS. 2A to 2D are schematic diagrams illustrating a method of fabricating a semiconductor device consistent with another example of the present invention;

FIGS. 3A to 3D are schematic diagrams illustrating a method of fabricating a semiconductor device consistent with still another example of the present invention; and

FIG. 4 is an example of a transmission electron microscope (TEM) photo illustrating a top view of a crystallized region of a semiconductor device fabricated in accordance with a method of the present invention.

### DETAILED DESCRIPTION OF THE INVENTION

Reference will now be made in detail to the present embodiments of the invention, examples of which are illustrated in the accompanying drawings. Wherever possible, the same reference numbers will be used throughout the drawings to refer to the same or like portions.

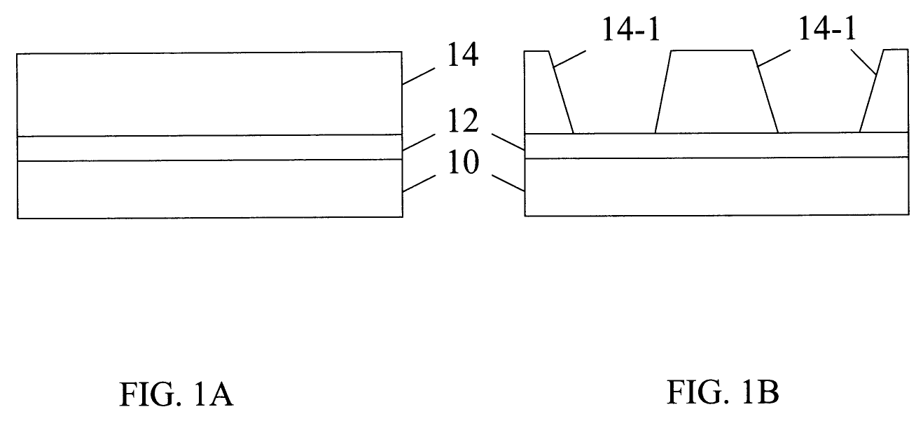

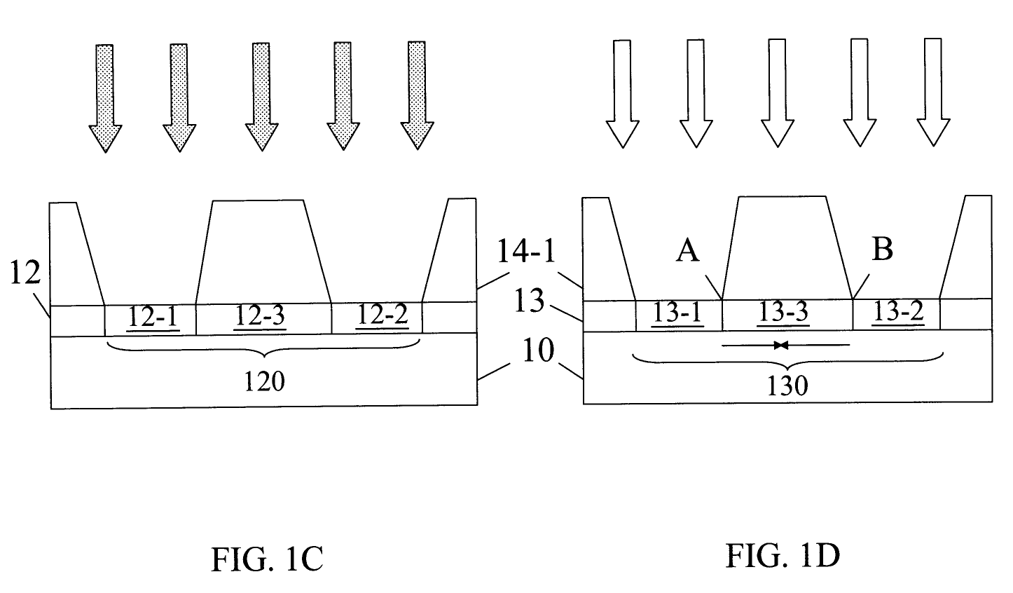

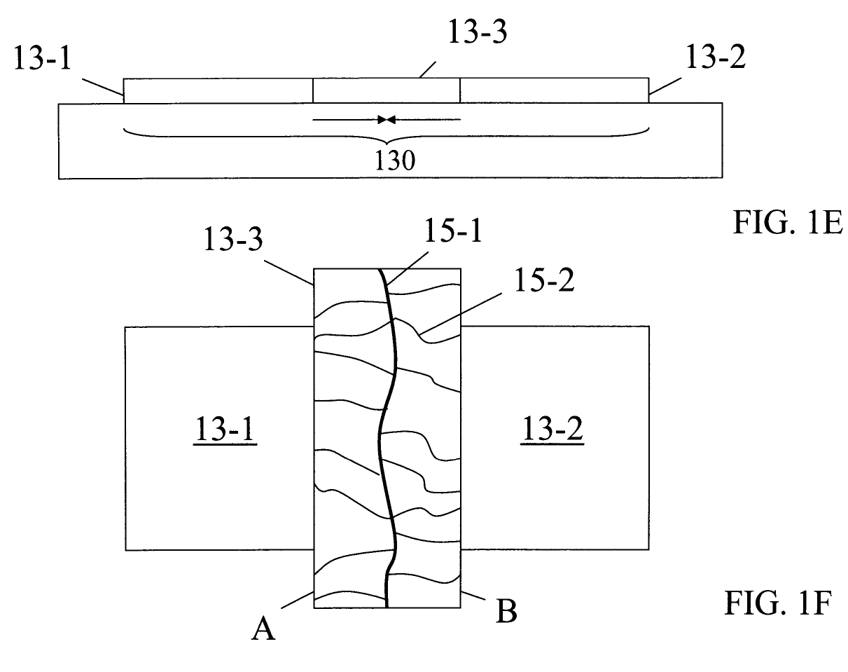

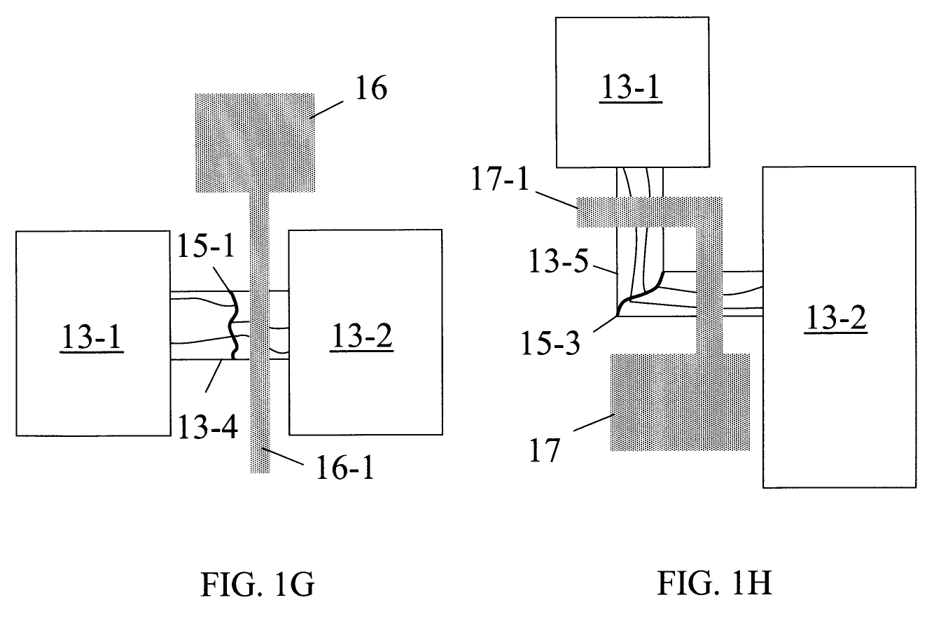

FIGS. 1A to 1H are schematic diagrams illustrating a method of fabricating a semiconductor device consistent with an example of the present invention. FIGS. 1A to 1E are schematic cross-sectional views illustrating the method. Referring to FIG. 1A, an amorphous silicon layer 12 is formed over a substrate 10 by, for example, a conventional plasma enhanced chemical vapor deposition (“PECVD”) process, a conventional physical vapor deposition (“PVD”) process or other suitable process. The amorphous silicon layer 12 is then de-hydrated by, for example, a dehydration bake conducted in a vacuum oven at approximately 450° C. for 2 hours, or a rapid thermal process (“RTP”). The substrate 10, made of such as glass or resin, has a thickness ranging from approximately 0.2 to 0.6 millimeter (mm) but the thickness could vary in particular applications. The amorphous silicon layer 12 has a thickness of approximately 50 nanometer (nm).

Next, a heat retaining layer 14 is formed on the amorphous silicon layer 12 by, for example, a conventional CVD process. The heat retaining layer 14 refers to one made of a material that absorbs a portion of an irradiating beam and transmits the remaining portion. The use of a heat retaining layer to control a main grain boundary has been discussed in U.S. patent application Ser. No. 11/226,679, entitled “Method of Semiconductor Thin Film Crystallization and Semiconductor Device Fabrication”, filed Sep. 14, 2005 by Jia-Xing Lin et al., who is one of the inventors of the present invention. Furthermore, the use of a heat retaining layer to achieve improved crystallization quality can be found in U.S. patent application Ser. No. 11/279,933, entitled “Thin Film Transistor (TFT) and Method for Fabricating the Same”, filed Apr. 17, 2006 by Jia-Xing Lin et al. In one example consistent with the present invention, the heat retaining layer 14 includes silicon oxynitride, which absorbs 30% of an irradiating beam. The heat retaining layer 14 has a thickness of approximately 0.4 to 0.6 micrometer (μm).

Referring to FIG. 1B, a patterned heat retaining layer 14-1 is formed by, for example, a conventional patterning and etching process to expose portions of the amorphous silicon layer 12. Next, referring to FIG. 1C, a pair of doped regions 12-1 and 12-2 are formed in the amorphous silicon layer 12 by doping one of an n-type impurity such as phosphor or a p-type impurity such as boron into the exposed portions by, for example, a conventional ion implanting process or other suitable process, using the patterned heat retaining layer 14-1 as a mask. The impurity density of the doped regions 12-1 and 12-2 ranges from approximately 8×10¹⁴ to 5×10¹⁵ cm⁻². The pair of doped regions 12-1 and 12-2 subsequently serve as a source and a drain, respectively, of a transistor being fabricated. A channel of the transistor is defined in a region 12-3 between the pair of doped regions 12-1 and 12-2. The doped regions 12-1, 12-2 and the region 12-3 together define an active region 120, i.e., a device site, of the transistor being fabricated.

The amorphous silicon layer 12 is then crystallized by, for example, an excimer laser process or other suitable process. Referring to FIG. 1D, a crystallized silicon layer 13 is formed by laser irradiation through the patterned heat retaining layer 14-1. The crystallized silicon layer 13 includes a crystallized active region 130, which includes a first activated region 13-1, a second activated region 13-2 and a crystallized region 13-3 between the first activated region 13-1 and the second activated region 13-2. The crystallization process may therefore crystallize the doped regions 12-1 and 12-2 as well as the region 12-3 illustrated in FIG. 1C, and activate the doped regions 12-1 and 12-2.

Suitable laser sources include but are not limited to frequency-doubled solid state laser beams such as Nd:YAG laser beams with a wavelength of approximately 532 nm (nanometer), Nd:YVO4 laser beams with a wavelength of approximately 532 nm and Nd:YLF laser beams with a wavelength of approximately 527 nm, and excimer laser beams such as xenon chloride (XeCl) laser beams with a wavelength of approximately 308 nm (nanometer) and krypton fluoride (KrF) laser beams with a wavelength of approximately 248 nm. The laser source provides the necessary energy to melt the region 12-3 underlying the patterned heat retaining layer 14-1. In one example consistent with the present invention, the laser energy ranges from approximately 400 to 800 mill joule per square centimeter (mJ/cm²). In another example, a laser beam having a beam diameter of 20 μm is irradiated at 20 shots per second. The laser beam moves with respect to amorphous silicon layer 12 and the defined heat retaining layer 14-1 with an irradiation position overlap of approximately 0.2 μm, or 1% of the beam diameter. As compared to conventional techniques having an irradiation position overlap ranging from approximately 50% to 95%, the 1% overlap in accordance with the present invention does greatly help improve the throughput.

Nucleation and crystalline growth commences from the initial nucleation sites A and B via lateral growth. In the lateral growth, a portion where a semiconductor is melted completely due to the irradiation of a laser beam, and a portion where the solid-phase semiconductor area remains, are formed, and then, the crystal growth begins around the solid-phase semiconductor area as the crystal nucleus. Since it takes a certain period of time for nucleation to take place in the completely melted area, during the period of time until the nucleation takes place in the completely melted area, the crystal grows around the above-described solid-phase semiconductor area as the crystal nucleus in the horizontal or lateral direction with respect to the film surface of the above-described semiconductor. Therefore, the crystal grain grows up to a length as long as several tens of times of the film thickness.

Referring to FIG. 1E, after the crystallization process, the patterned heat retaining layer 14-1 is removed by, for example, a conventional etching process using a mixture of hydrofluoric acid (HF) and ammonium fluoride NH₃F. The crystallized layer 13 except the crystallized active region 130 is then removed.

FIG. 1F is a schematic top view of the crystallized active region 130 illustrated in FIG. 1E. Referring to FIG. 1F, grain boundaries including a main grain boundary 15-1 and plural sub-boundaries 15-2 are formed in the crystallized region 13-3 during the nucleation and crystal growth. In particular, the main grain boundary 15-1 extending in a direction in parallel with the initial nucleation site A and B and substantially across the crystallized active region 130 of the TFT device is expected to be formed at a center region between the sites A and B. A grain boundary of a crystal grain refers to an area where the translational symmetry of the crystal is decayed. It is known that, due to the influence of the recombination center or trapping center of the carrier, or the influence of the potential barrier in the crystal grain boundary caused from the crystal defect or the like, the current transport characteristics of the carrier is decreased, and as a result, the OFF-current increases in the TFT. For example, the main grain boundary 15-1 may adversely affect the mobility of carriers, which move across the center region during current transport.

FIG. 1G is a schematic top view of a single-gate structure of a transistor being fabricated in accordance with a method consistent with an example of the present invention. Referring to FIG. 1G, a patterned crystallized region 13-4 is formed by removing portions of the crystallized region 13-3 by, for example, a conventional etching and patterning process or other suitable process. An insulating layer (not shown) is then formed over the patterned crystallized region 13-4 by, for example, a conventional PECVD process or other suitable process. Suitable materials for the insulating layer include silicon nitride, silicon oxide and silicon oxynitride. The thickness of the insulating layer ranges from approximately 70 to 400 nm. Next, a gate structure 16 having a single finger 16-1 is formed over the patterned crystallized region 13-4 by forming a metal layer in a conventional PVD process followed by a conventional patterning and etching process. The finger 16-1 extends across the patterned crystallized region 13-4 without overlapping the main grain boundary 15-1. In another example, however, the finger 16-1 may overlap the main grain boundary 15-1. Suitable materials for the gate structure 16 include but are not limited to TiAlTi, MoAlMo, CrAlCr, MoW, Cr and Cu. The thickness of the gate structure 16 ranges from approximately 100 to 300 nm but could be other thickness.

FIG. 1H is a schematic top view of a dual-gate structure of a transistor being fabricated in accordance with a method consistent with another example of the present invention. Referring to FIG. 1H, a patterned crystallized region 13-5 extending in a winding path between the activated regions 13-1 and 13-2 is formed. Subsequently, a gate structure 17 having a finger 17-1 extending in a winding path is formed over the patterned crystallized region 13-5. The finger 17-1 extends across the patterned crystallized region 13-5 at least twice without overlapping a main grain boundary 15-3.

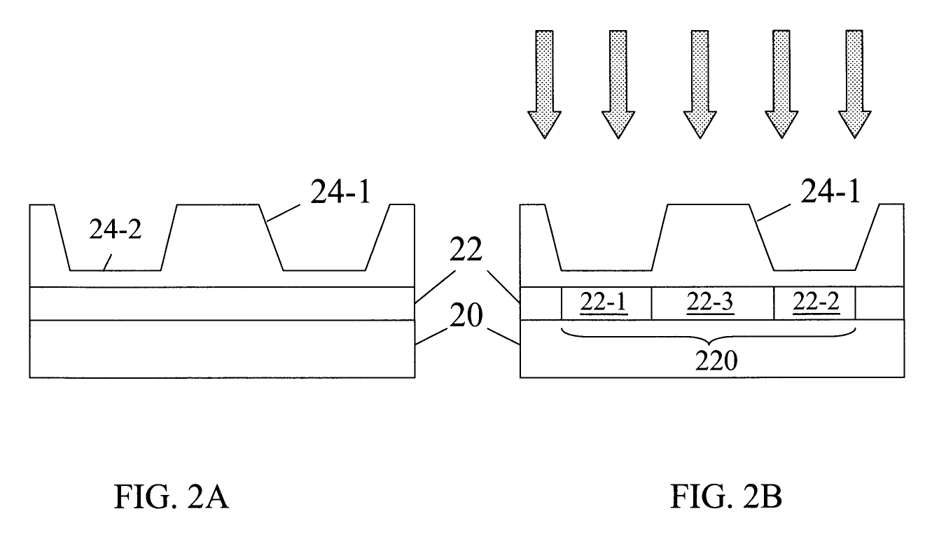

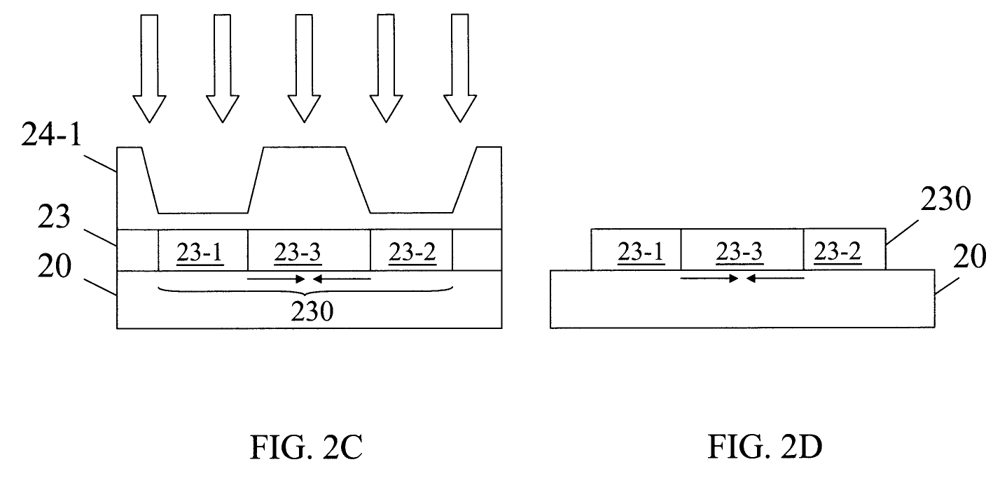

FIGS. 2A to 2D are schematic diagrams illustrating a method of fabricating a semiconductor device consistent with another example of the present invention. Referring to FIG. 2A, an amorphous silicon layer 22 is formed on a substrate 20. Next, a patterned heat retaining layer 24-1 is formed on the amorphous silicon layer 22 without exposing the amorphous silicon layer 22. The patterned heat retaining layer 24-1 has a thickness ranging from approximately 0.4 to 0.6 μm, and a remaining heat retaining layer 24-2 has a thickness ranging from 0.05 to 0.2 μm. The remaining heat retaining layer 24-2 may serve as an etch buffer to prevent over-etching of an underlying amorphous silicon layer, and may serve as a buffer layer to facilitate control of doping dosage by, for example, adjusting the buffer layer thickness at a subsequent process.

Referring to FIG. 2B, a pair of doped regions 22-1 and 22-2 are formed in the amorphous silicon layer 22 by an ion implanting process or other suitable process. The pair of doped regions 22-1 and 22-2 subsequently serve as a source and a drain, respectively, of a transistor being fabricated. A channel of the transistor is defined in a region 22-3 between the pair of doped regions 22-1 and 22-2. The doped regions 22-1, 22-2 and the region 22-3 together define an active region 220 of the transistor being fabricated.

Next, referring to FIG. 2C, a crystallized silicon layer 23 is formed by laser irradiation through the patterned heat retaining layer 24-1. The crystallized silicon layer 23 includes a crystallized active region 230, which includes a first activated region 23-1, a second activated region 23-2 and a crystallized region 23-3 between the first activated region 23-1 and the second activated region 23-2. In one example consistent with the present invention, the laser energy employed in the crystallization process ranges from approximately 400 to 1000 mJ/cm².

Next, referring to FIG. 2D, after the crystallization process, the patterned heat retaining layer 24-1 and the crystallized layer 23 are removed except the crystallized active region 230. The subsequent processes for fabricating the semiconductor device are similar to those described with respect to FIG. 1G or 1H and are not discussed.

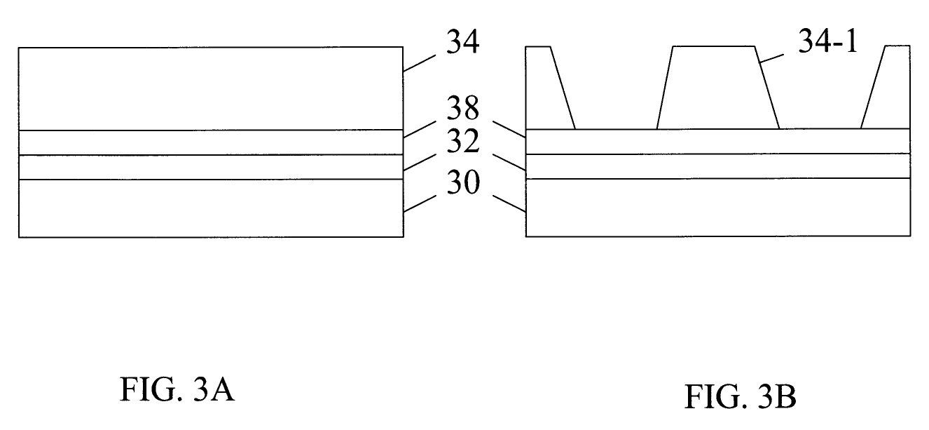

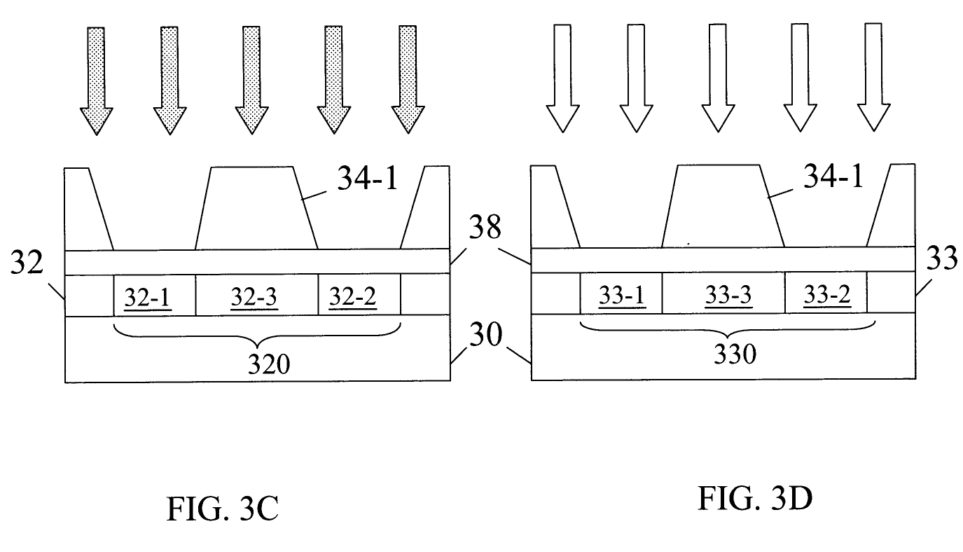

FIGS. 3A to 3D are schematic diagrams illustrating a method of fabricating a semiconductor device consistent with still another example of the present invention. Referring to FIG. 3A, an amorphous silicon layer 32 is formed on a substrate 30. Next, an insulating layer 38 is formed on the amorphous silicon layer 32 by, for example, a conventional PECVD process or other suitable process. The insulating layer 38 functions to serve as an etch buffer or a doping buffer. Suitable materials for the insulating layer 38 include silicon nitride, silicon oxide and silicon oxynitride. In one example consistent with the present invention, the insulating layer 38 may include silicon dioxide (SiO₂). The thickness of the insulating layer 38 ranges from approximately 0.05 to 0.2 μm. Next, a heat retaining layer 34 is formed on the insulating layer 38.

Referring to FIG. 3B, a patterned heat retaining layer 34-1 is formed by a conventional patterning and etching process or other suitable process, exposing portions of the insulating layer 38.

Referring to FIG. 3C, a pair of doped regions 32-1 and 32-2 are formed in the amorphous silicon layer 32 by an ion implanting process or other suitable process, using the patterned heat retaining layer 34-1 as a mask. The pair of doped regions 32-1 and 32-2 subsequently serve as a source and a drain, respectively, of a transistor being fabricated. A channel of the transistor is defined in a region 32-3 between the pair of doped regions 32-1 and 32-2. The doped regions 32-1, 32-2 and the region 32-3 together define an active region 320 of the transistor being fabricated.

Referring to FIG. 3D, a crystallized silicon layer 33 is formed by laser irradiation through the patterned heat retaining layer 34-1 and the insulating layer 38. The crystallized silicon layer 33 includes a crystallized active region 330, which includes a first activated region 33-1, a second activated region 33-2 and a crystallized region 33-3 between the first activated region 33-1 and the second activated region 33-2. In one example consistent with the present invention, the laser energy ranges from approximately 400 to 1000 mJ/cm².

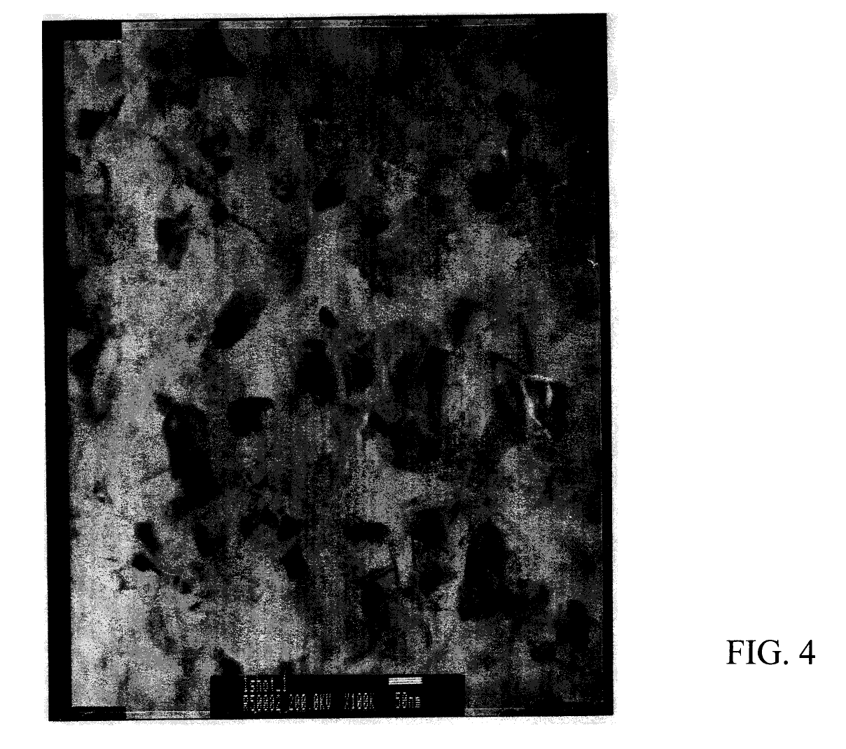

FIG. 4 is an example of a transmission electron microscope (TEM) photo illustrating a top view of a crystallized region of a semiconductor device fabricated in accordance with a method of the present invention. In an experiment on the crystallized region, in which twelve samples are taken, the sheet resistance of the crystallized region falls within the range of 440 to 500 ohm per square centimeter (Ω/cm²), which is a desirable range of activation. Furthermore, an average grain size of the crystallized region is approximately 50 nm, which is a desirable value of crystallization.

It will be appreciated by those skilled in the art that changes could be made to one or more of the examples described above without departing from the broad inventive concept thereof. It is understood, therefore, that this invention is not limited to the particular examples disclosed, but it is intended to cover modifications within the scope of the present invention as defined by the appended claims.

Further, in describing certain illustrative examples of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

We claim:

1. A method of fabricating a semiconductor device, comprising:
providing a substrate;
forming an amorphous silicon layer over the substrate;
forming a patterned heat retaining layer over the amorphous silicon layer;
doping the amorphous silicon layer to form a pair of doped regions in the amorphous silicon layer by using the patterned heat retaining layer as a mask; and
irradiating the amorphous silicon layer to activate the pair of doped regions, forming a pair of activated regions, and form a crystallized region between the pair of activated regions.

2. The method of claim 1, wherein forming a patterned heat retaining layer over the amorphous silicon layer further comprises:
forming a heat retaining layer on the amorphous silicon layer; and
patterning the heat retaining layer to form the patterned heat retaining layer, exposing portions of the amorphous silicon layer.

3. The method of claim 1, wherein forming a patterned heat retaining layer over the amorphous silicon layer further comprises:
forming a heat retaining layer on the amorphous silicon layer; and
patterning the heat retaining layer to form the patterned heat retaining layer without exposing the amorphous silicon layer.

4. The method of claim 1, wherein forming a patterned heat retaining layer over the amorphous silicon layer further comprises:
forming an insulating layer on the amorphous silicon layer; and
forming the patterned heat retaining layer on the insulating layer, exposing portions of the insulating layer.

5. The method of claim 1, further comprising:
forming a patterned crystallized region between the pair of activated regions; and
forming a gate structure extending over the patterned crystallized region.

6. The method of claim 1, further comprising:
forming a patterned crystallized region between the pair of activated regions, the patterned crystallized region extending in a winding path between the pair of activated regions.

7. The method of claim 6, further comprising:
forming a gate structure extending in a winding path over the patterned crystallized region.

8. The method of claim 6, further comprising:
forming a gate structure over the patterned crystallized region to extend at least twice across the patterned crystallized region.

9. A method of fabricating a semiconductor device, comprising:
providing a substrate;
forming an amorphous silicon layer over the substrate;
forming a heat retaining layer over the amorphous silicon layer;
patterning the heat retaining layer to form a patterned heat retaining layer without exposing the amorphous silicon layer;
doping the amorphous silicon layer through the patterned heat retaining layer to form a pair of doped regions in the amorphous silicon layer; and
activating the pair of doped regions to form a pair of activated regions, and forming a crystallized region between the pair of activated regions by irradiating the amorphous silicon layer through the patterned heat retaining layer.

10. The method of claim 9, further comprising:
irradiating the amorphous silicon layer with one of an excimer laser, Nd:YAG laser, Nd:YVO4 laser and Nd:YLF laser.

11. The method of claim 9, further comprising:
irradiating the amorphous silicon layer with an irradiation position overlap of approximately 1% of a beam diameter.

12. The method of claim 9, further comprising:
forming a patterned crystallized region between the pair of activated regions; and
forming a gate structure extending over the patterned crystallized region.

13. The method of claim 9, further comprising:
forming a patterned crystallized region between the pair of activated regions, the patterned crystallized region extending in a winding path between the pair of activated regions.

14. The method of claim 13, further comprising:
forming a gate structure extending in a winding path over the patterned crystallized region.

15. A method of fabricating a semiconductor device, comprising:
providing a substrate;
forming an amorphous silicon layer over the substrate;
forming an insulating layer over the amorphous silicon layer;
forming a patterned heat retaining layer over the insulating layer;
doping the amorphous silicon layer to form a pair of doped regions in the amorphous silicon layer; and
activating the pair of doped regions to form a pair of activated regions, and forming a crystallized region between the pair of activated regions by irradiating the amorphous silicon layer through the patterned heat retaining layer.

16. The method of claim 15, wherein forming a patterned heat retaining layer over the insulating layer further comprises:
forming a heat retaining layer on the insulating layer; and
patterning the heat retaining layer to form the patterned heat retaining layer, exposing portions of the insulating layer.

17. The method of claim 15, further comprising:
forming the patterned heat retaining layer with silicon oxynitride.

18. The method of claim 15, further comprising:
forming a patterned crystallized region between the pair of activated regions; and
forming a gate structure extending over the patterned crystallized region.

19. The method of claim 15, further comprising:
forming a patterned crystallized region between the pair of activated regions, the patterned crystallized region extending in a winding path between the pair of activated regions.

20. The method of claim 15, further comprising:
forming a gate structure extending in a winding path over the patterned crystallized region.
